(19) United States
(12) Patent Application Publication
(10) Pub. No.: US 2026/0040838 A1
(43) Pub. Date: Feb. 5, 2026

(54) ATOMIC LAYER DEPOSITION METHOD

(71) Applicant: JUSUNG ENGINEERING CO., LTD., Gwangju-si, Gyeonggi-do (KR)

(72) Inventors: Chul Joo HWANG, Yongin-si, Gyeonggi-do (KR); Il Houng PARK, Yongin-si, Gyeonggi-do (KR); Duck Ho KIM, Yongin-si, Gyeonggi-do (KR); Won Tae CHO, Yongin-si, Gyeonggi-do (KR)

(21) Appl. No.: 19/099,764

(22) PCT Filed: Jul. 26, 2023
(86) PCT No.: PCT/KR2023/010842

§ 371 Date: Jan. 29, 2025

(30) Foreign Application Priority Data
Aug. 10, 2022 (KR) 10-2022-0099635
Aug. 23, 2022 (KR) 10-2022-0105467

(51) Int. Cl. H01L 21/02; C23C 16/40; C23C 16/455; H10D 30/01; H10D 30/67

(52) U.S. Cl. CPC H01L 21/0262; C23C 16/407; C23C 16/45527; H01L 21/02565; H10D 30/0316; H10D 30/6732; H10D 30/6755

(57) ABSTRACT

The present inventive concept relates to an atomic layer deposition (ALD) method for forming an IGZO channel layer of a transistor device the method comprising: a deposition cycle step of performing a deposition cycle for depositing an IGZO channel layer on a substrate; and a repeat step of repeatedly performing the deposition cycle step until the IGZO channel layer is formed with a predetermined thickness, wherein in the deposition cycle step, the IGZO channel layer is formed by performing an indium oxide sub-cycle for depositing indium oxide (InO), a gallium oxide sub-cycle for depositing gallium oxide (GaO), and a zinc oxide sub-cycle for depositing zinc oxide (ZnO).

### TECHNICAL FIELD

The present inventive concept relates to an atomic layer deposition method for depositing an oxide semiconductor thin film on a substrate.

### BACKGROUND ART

An oxide semiconductor is formed of metal oxide among semiconductors and may be deposited on a substrate in a process of manufacturing an electronic device such as a display device or a solar cell, and thus, may be implemented as an oxide semiconductor thin film.

For example, an IGZO layer formed of indium (In), gallium (Ga), zinc (Zn), and oxygen (O) may be deposited on a substrate in a process of manufacturing a transistor device of an electronic device and may be implemented as an oxide semiconductor thin film.

Such an IGZO layer has a characteristic where electron mobility is good and the leakage of a current is small, and thus, is attracting much attention as a thin film important for enhancing the performance of a transistor device. Also, in materials configuring the IGZO layer, indium is relevant to a carrier function for electron mobility, gallium is relevant to a carrier function for the leakage of a current, zinc is relevant to a carrier function for chemical structure stabilization, and oxygen is relevant to a carrier function for electrical conduction. In consideration of this, it is required to develop an atomic layer deposition (ALD) method capable of depositing an IGZO layer having enhanced performance by using indium, gallium, zinc, and oxygen.

### DISCLOSURE

### Technical Problem

The present inventive concept is devised to solve the above-described problem and is for providing an atomic layer deposition method capable of depositing an IGZO layer having enhanced performance by using indium, gallium, zinc, and oxygen.

### Technical Solution

To accomplish the above-described objects, the present inventive concept may include the following elements.

An atomic layer deposition method according to the present inventive concept is an atomic layer deposition (ALD) method for forming an IGZO channel layer of a transistor device may include: a deposition cycle step of performing a deposition cycle for depositing an IGZO channel layer on a substrate; and a repetition step of repeatedly performing the deposition cycle step until the IGZO channel layer having a predetermined thickness is formed. The deposition cycle step may perform an indium oxide sub-cycle for depositing indium oxide (InO), a gallium oxide sub-cycle for depositing gallium oxide (GaO), and a zinc oxide sub-cycle for depositing zinc oxide (ZnO) to deposit the IGZO channel layer.

An atomic layer deposition method according to the present inventive concept is an atomic layer deposition (ALD) method for forming an IGZO channel layer of a transistor device may include: a deposition cycle step of performing a deposition cycle for depositing an IGZO channel layer on a substrate; and a repetition step of repeatedly performing the deposition cycle step until the IGZO channel layer having a predetermined thickness is formed. The deposition cycle step may include: a gallium indium oxide deposition step of sequentially performing, at least once, a gallium oxide sub-cycle for depositing gallium oxide (GaO) and an indium oxide sub-cycle for depositing indium oxide (InO); and a zinc oxide deposition step of performing, at least once, a zinc oxide sub-cycle for depositing zinc oxide (ZnO).

An atomic layer deposition method according to the present inventive concept is an atomic layer deposition (ALD) method for forming an IGZO channel layer of a transistor device may include: a deposition cycle step of performing a deposition cycle for depositing an IGZO channel layer on a substrate; and a repetition step of repeatedly performing the deposition cycle step until the IGZO channel layer having a predetermined thickness is formed. The deposition cycle step may include: a gallium indium oxide deposition step of sequentially performing, at least once, an indium oxide sub-cycle for depositing indium oxide (InO) and a gallium oxide sub-cycle for depositing gallium oxide (GaO); and a zinc oxide deposition step of performing, at least once, a zinc oxide sub-cycle for depositing zinc oxide (ZnO).

### Advantageous Effect

According to the present inventive concept, the following effects may be realized.

The present inventive concept individually deposits indium oxide, gallium oxide, and zinc oxide on a substrate through an atomic layer deposition process, and thus, is implemented to form an IGZO channel layer. Accordingly, the present inventive concept may enhance the whole film quality of the IGZO channel layer, and thus, may contribute to enhancing the performance of a transistor device.

The present inventive concept is implemented to enhance the accuracy and easiness of an operation of controlling a composition ratio of indium, gallium, and zinc to correspond to the kind and spec of a transistor device. Accordingly, the present inventive concept may enhance response capability to changing of the kind and spec of a transistor device and may enhance the general purpose capable of being applied to formation of IGZO channel layers of various transistor devices.

The present inventive concept may be implemented to include a gallium indium oxide deposition step of depositing gallium oxide and indium oxide. In this case, a step coverage of an IGZO channel layer may be improved.

### DESCRIPTION OF DRAWINGS

FIG. 1 is a schematic block diagram illustrating an embodiment of an atomic layer deposition apparatus performing an atomic layer deposition method according to the present inventive concept.

FIGS. 2 and 3 are schematic side cross-sectional views of an injection unit injecting a gas in an embodiment of an atomic layer deposition apparatus performing an atomic layer deposition method according to the present inventive concept.

FIG. 4 is a schematic side cross-sectional view illustrating an embodiment of a transistor device.

FIGS. 5 to 9 are schematic flowcharts of an atomic layer deposition method according to the present inventive concept.

### MODE FOR INVENTIVE CONCEPT

Hereinafter, an embodiment of an atomic layer deposition method according to the present inventive concept will be described in detail with reference to the accompanying drawings. In describing an embodiment of the present inventive concept, when an arbitrary structure is described as being formed “on” or “under” another structure, this description should be construed as including a case, where a third structure is disposed between the structures, as well as a case where the structures contact each other.

Referring to FIGS. 1 to 4, an atomic layer deposition method according to the present inventive concept forms an oxide semiconductor thin film on a substrate S through an atomic layer deposition (ALD) process. The substrate S may be a silicon substrate, a glass substrate, a metal substrate, or the like. The atomic layer deposition method according to the present inventive concept may form an IGZO layer on the substrate S by using indium (In), gallium (Ga), zinc (Zn), and oxygen (O). Such an IGZO layer may be implemented as a channel layer in a transistor device of an electronic device such as a display device or a solar cell.

The atomic layer deposition method according to the present inventive concept may be performed by an atomic layer deposition apparatus 1. Before describing an embodiment of the atomic layer deposition method according to the present inventive concept, an example of the atomic layer deposition apparatus 1 will be described below in detail.

Referring to FIGS. 1 to 3, the atomic layer deposition apparatus 1 may include a chamber 2, a susceptor 3, and an injection unit 4.

The chamber 2 provides a processing space 100. A process of forming an IGZO channel layer of a transistor on the substrate S through an atomic layer deposition process may be performed in the processing space 100. The processing space 100 may be disposed in the chamber 2. An exhaust port (not shown) which exhausts a gas from the processing space 100 may be coupled to the chamber 2. The susceptor 3 and the injection unit 4 may be disposed in the chamber 2.

The susceptor 3 supports the substrate S. The susceptor 3 may support one substrate S, or may support a plurality of substrates S. In a case where the plurality of substrates S are supported by the susceptor 3, a process of forming the IGZO channel layer on the substrates S through an atomic layer deposition process on the plurality of substrates S at a time may be performed. The susceptor 3 may be coupled to the chamber 2. The susceptor 3 may be disposed in the chamber 2.

The injection unit 4 injects a gas toward the susceptor 3. The injection unit 4 may be connected with a gas storage unit 40. In this case, the injection unit 4 may inject a gas, supplied from the gas storage unit 40, toward the susceptor 3. The injection unit 4 may be disposed in the chamber 2. The injection unit 4 may be disposed to be opposite to the susceptor 3. The injection unit 4 may be disposed over the susceptor 3. The processing space 100 may be disposed between the injection unit 4 and the susceptor 3. The injection unit 4 may be coupled to a lid (not shown). The lid may be coupled to the chamber 2 to cover an upper portion of the chamber 2.

The injection unit 4 may include a first gas flow path 4a and a second gas flow path 4b.

The first gas flow path 4a is for injecting a first gas. One side of the first gas flow path 4a may be connected with the gas storage unit 40 through a pipe, a hose, or the like. The other side of the first gas flow path 4a may communicate with the processing space 100. Accordingly, the first gas supplied from the gas storage unit 40 may flow along the first gas flow path 4a, and then, may be injected into the processing space 100 through the first gas flow path 4a. The first gas flow path 4a may function as a flow path for enabling the first gas to flow and may function as an injection port for injecting the first gas into the processing space 100.

The second gas flow path 4b is for injecting a second gas. The second gas and the first gas may be different gases. For example, when the first gas is a source gas, the second gas may be a reactant gas. One side of the second gas flow path 4b may be connected with the gas storage unit 40 through a pipe, a hose, or the like. The other side of the second gas flow path 4b may communicate with the processing space 100. Accordingly, the second gas supplied from the gas storage unit 40 may flow along the second gas flow path 4b, and then, may be injected into the processing space 100 through the second gas flow path 4b. The second gas flow path 4b may function as a flow path for enabling the second gas to flow and may function as an injection port for injecting the second gas into the processing space 100.

The second gas flow path 4b and the first gas flow path 4a may be disposed to be spatially separated from each other. Therefore, the second gas supplied from the gas storage unit 40 to the second gas flow path 4b may be injected into the processing space 100 without passing through the first gas flow path 4a. The first gas supplied from the gas storage unit 40 to the second gas flow path 4b may be injected into the processing space 100 without passing through the second gas flow path 4b. The second gas flow path 4b and the first gas flow path 4a may inject a gas toward different portions of the processing space 100.

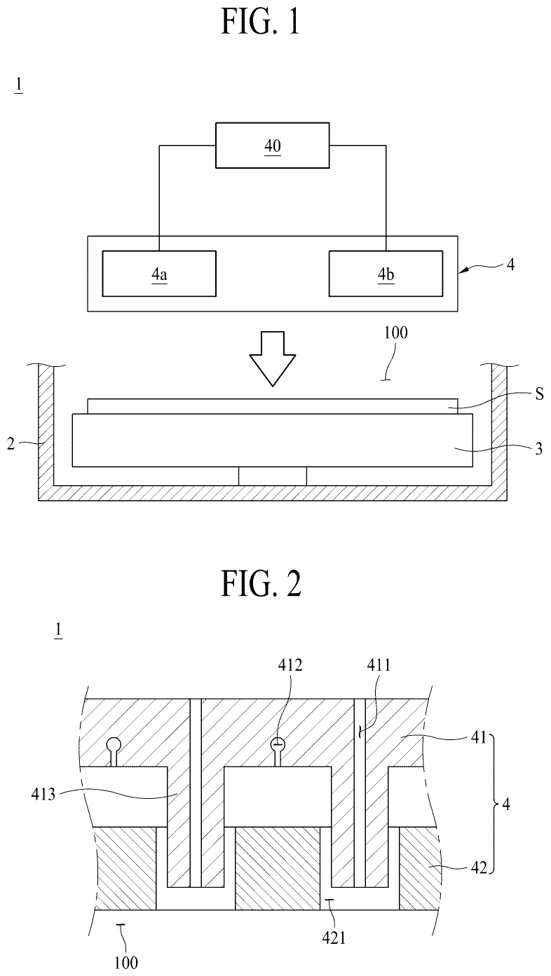

As illustrated in FIG. 2, the injection unit 4 may include a first plate 41 and a second plate 42.

The first plate 41 is disposed over the second plate 42. The first plate 41 and the second plate 42 may be disposed apart from each other. A plurality of first gas holes 411 may be formed in the first plate 41. Each of the first gas holes 411 may function as a path for enabling the first gas to flow. The first gas holes 411 may be included in the first gas flow path 4a. A plurality of second gas holes 412 may be formed in the second plate 42. Each of the second gas holes 412 may function as a path for enabling the second gas to flow. The second gas holes 412 may be included in the second gas flow path 4b. A plurality of protrusion members 413 may be coupled to the first plate 41. The protrusion members 413 may protrude toward the second plate 42 from a lower surface of the first plate 41. Each of the first gas holes 411 may be formed to pass through the first plate 41 and the protrusion member 413.

A plurality of openings 421 may be formed in the second plate 42. The openings 421 may be formed to pass through the second plate 42. The openings 421 may be disposed at position respectively corresponding to the protrusion members 413. Therefore, as illustrated in FIG. 2, the protrusion members 413 may be formed by a length which enables the protrusion members 413 to be respectively inserted into the openings 421. Although not shown, the protrusion members 413 may be formed by a length which enables the protrusion members 413 to be respectively disposed over the openings 421. The protrusion members 413 may be formed by a length which protrudes downward from the second plate 42. The second gas holes 412 may be disposed to inject a gas toward an upper surface of the second plate 42.

The injection unit 4 may generate plasma by using the second plate 42 and the first plate 41. In this case, a plasma power such as radio frequency (RF) power may be applied to the first plate 41, and the second plate 42 may be grounded. The first plate 41 may be grounded, and the plasma power may be applied to the second plate 42.

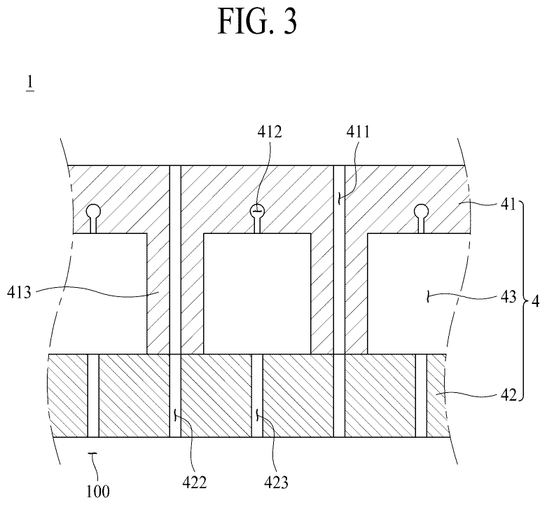

As illustrated in FIG. 3, a plurality of first openings 422 and a plurality of second openings 423 may be formed in the second plate 42.

The first openings 422 may be formed to pass through the second plate 42. The first openings 422 may be respectively connected with the first gas holes 411. In this case, the protrusion members 413 may be disposed to contact an upper surface of the second plate 42. The first gas may be injected into the processing space 100 via the first gas holes 411 and the first openings 422. The first gas holes 411 and the first openings 422 may be included in the first gas flow path 4a.

The second openings 423 may be formed to pass through the second plate 42. The second openings 423 may be respectively connected with a buffer space 43 disposed between the first plate 41 and the second plate 42. The second gas may be injected into the processing space 100 via the second gas holes 412, the buffer space 43, and the second openings 423. The second gas holes 412, the buffer space 43, and the second openings 423 may be included in the second gas flow path 4b.

The atomic layer deposition method according to the present inventive concept may be performed by the atomic layer deposition apparatus 1.

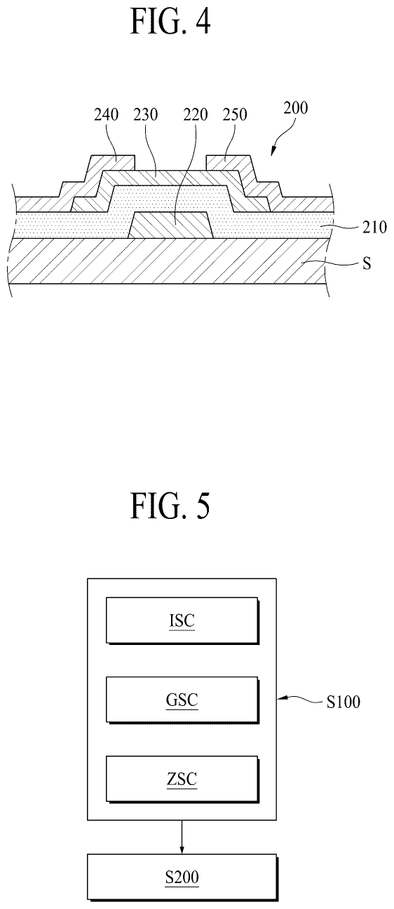

Referring to FIGS. 1 to 5, as illustrated in FIG. 4, the atomic layer deposition method according to the present inventive concept may form an IGZO channel layer 230 in a transistor device 200 including an insulation layer 210, a gate electrode 220, the IGZO channel layer 230, a source electrode 240, and a drain electrode 250. The insulation layer 210 may be disposed between the gate electrode 220 and the IGZO channel layer 230. The gate electrode 220 may be formed on the substrate S. The IGZO channel layer 230 may be formed on the insulation layer 210. The source electrode 240 and the drain electrode 250 may be formed on the IGZO channel layer 230.

The atomic layer deposition method according to the present inventive concept may include a deposition cycle step S100 and a repetition step S200.

The deposition cycle step S100 performs a deposition cycle for depositing the IGZO channel layer 230 on the substrate S. The deposition cycle step S100 may perform the deposition cycle by using indium, gallium, zinc, and oxygen, and thus, may deposit the IGZO channel layer 230 on the substrate S.

The repetition step S200 repeatedly performs the deposition cycle step S100. The repetition step S200 may repeatedly perform the deposition cycle step S100 until the IGZO channel layer 230 having a predetermined thickness is formed. Here, the predetermined thickness may be changed based on the kind and spec of the transistor device 200 and may be previously set by a worker.

Here, the deposition cycle step S100 may perform an indium oxide sub-cycle ISC for depositing indium oxide (InO), a gallium oxide sub-cycle GSC for depositing gallium oxide (GaO), and a zinc oxide sub-cycle ZSC for depositing zinc oxide (ZnO) to deposit the IGZO channel layer 230. Therefore, the atomic layer deposition method according to the present inventive concept may be implemented to individually deposit the indium oxide, the gallium oxide, and the zinc oxide on the substrate S to form the IGZO channel layer 230, and thus, may enhance the whole film quality of the IGZO channel layer 230. Accordingly, the atomic layer deposition method according to the present inventive concept may enhance the performance of the IGZO channel layer 230 through the enhancement of film quality, and thus, may contribute to enhancing the performance of the transistor device 200. Also, the atomic layer deposition method according to the present inventive concept is implemented to individually deposit the gallium oxide and the zinc oxide on the substrate S, and thus, may enhance the accuracy and easiness of an operation of controlling a composition ratio of indium, gallium, and zinc to correspond to the kind and spec of a transistor device. Accordingly, the atomic layer deposition method according to the present inventive concept may enhance response capability to changing of the kind and spec of the transistor device 200 and may enhance the general purpose capable of being applied to formation of IGZO channel layers of various transistor devices 200.

The indium oxide sub-cycle ISC may sequentially perform the injection of a source gas including indium and the injection of a reactant gas including oxygen to deposit the indium oxide through an atomic layer deposition process. The indium oxide sub-cycle ISC may sequentially perform, a plurality of times, the injection of the source gas including indium and the injection of the reactant gas including oxygen to deposit the indium oxide through an atomic layer deposition process. As described above, the atomic layer deposition method according to the present inventive concept may enhance the film quality of indium oxide deposited on the substrate S through the indium oxide sub-cycle ISC, and thus, may enhance the film quality of the IGZO channel layer 230. The source gas including indium may be injected toward the substrate S through the first gas flow path 4a. The reactant gas including oxygen may be injected toward the substrate S through the second gas flow path 4b.

The gallium oxide sub-cycle GSC may sequentially perform the injection of a source gas including gallium and the injection of the reactant gas including oxygen to deposit the gallium oxide through an atomic layer deposition process. The gallium oxide sub-cycle GSC may sequentially perform, a plurality of times, the injection of the source gas including gallium and the injection of the reactant gas including oxygen to deposit the gallium oxide through an atomic layer deposition process. As described above, the atomic layer deposition method according to the present inventive concept may enhance the film quality of gallium oxide deposited on the substrate S through the gallium oxide sub-cycle GSC, and thus, may enhance the film quality of the IGZO channel layer 230. The source gas including gallium may be injected toward the substrate S through the first gas flow path 4a. The reactant gas including oxygen may be injected toward the substrate S through the second gas flow path 4b.

The zinc oxide sub-cycle ZSC may sequentially perform the injection of a source gas including zinc and the injection of the reactant gas including oxygen to deposit the zinc oxide through an atomic layer deposition process. The zinc oxide sub-cycle ZSC may sequentially perform, a plurality of times, the injection of the source gas including zinc and the injection of the reactant gas including oxygen to deposit the zinc oxide through an atomic layer deposition process. As described above, the atomic layer deposition method according to the present inventive concept may enhance the film quality of zinc oxide deposited on the substrate S through the zinc oxide sub-cycle ZSC, and thus, may enhance the film quality of the IGZO channel layer 230. The source gas including zinc may be injected toward the substrate S through the first gas flow path 4a. The reactant gas including oxygen may be injected toward the substrate S through the second gas flow path 4b.

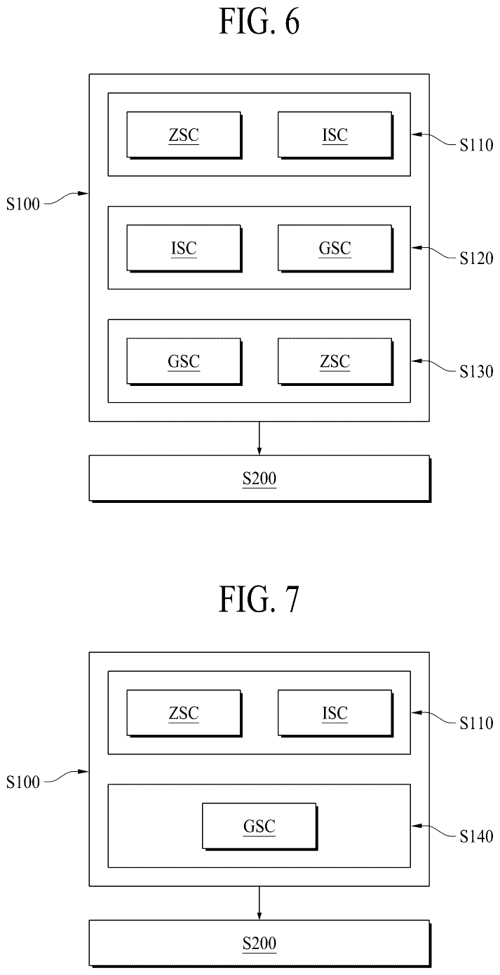

Referring to FIGS. 1 to 6, the deposition cycle step S100 may include a zinc indium oxide deposition step S110.

The zinc indium oxide deposition step S110 sequentially performs the zinc oxide sub-cycle ZSC and the indium oxide sub-cycle ISC. The zinc oxide and the indium oxide may be sequentially deposited on the substrate S through the zinc indium oxide deposition step S110, and thus, the zinc indium oxide may be formed on the substrate S. The zinc indium oxide deposition step S110 may sequentially perform the zinc oxide sub-cycle ZSC and the indium oxide sub-cycle ISC a plurality of times. In the zinc indium oxide deposition step S110, each of the source gas including zinc and the source gas including indium may be injected toward the substrate S through the first gas flow path 4a, and the reactant gas including oxygen may be injected toward the substrate S through the second gas flow path 4b.

Referring to FIGS. 1 to 6, the deposition cycle step S100 may include a gallium indium oxide deposition step S120.

The gallium indium oxide deposition step S120 sequentially performs the gallium oxide sub-cycle GSC and the indium oxide sub-cycle ISC. The gallium oxide and the indium oxide may be sequentially deposited on the substrate S through the gallium indium oxide deposition step S120, and thus, the gallium indium oxide may be formed on the substrate S. The gallium indium oxide deposition step S120 may sequentially perform the gallium oxide sub-cycle GSC and the indium oxide sub-cycle ISC a plurality of times. In the gallium indium oxide deposition step S120, each of the source gas including gallium and the source gas including indium may be injected toward the substrate S through the first gas flow path 4a, and the reactant gas including oxygen may be injected toward the substrate S through the second gas flow path 4b. Based on the gallium indium oxide deposition step S120 of depositing indium oxide after gallium oxide is deposited, the atomic layer deposition method according to the present disclosure may improve a step coverage of the IGZO channel layer 230.

The gallium indium oxide deposition step S120 may sequentially perform the indium oxide sub-cycle ISC and the gallium oxide sub-cycle GSC. The indium oxide and the gallium oxide may be sequentially deposited on the substrate S through the gallium indium oxide deposition step S120, and thus, the gallium indium oxide may be formed on the substrate S. The gallium indium oxide deposition step S120 may sequentially perform the indium oxide sub-cycle ISC and the gallium oxide sub-cycle GSC a plurality of times. As described above, based on the gallium indium oxide deposition step S120 of depositing gallium oxide after indium oxide is deposited, the atomic layer deposition method according to the present disclosure may improve a step coverage of the IGZO channel layer 230.

Referring to FIGS. 1 to 6, the deposition cycle step S100 may include a gallium zinc oxide deposition step S130.

The gallium zinc oxide deposition step S130 sequentially performs the gallium oxide sub-cycle GSC and the zinc oxide sub-cycle ZSC. The gallium oxide and the zinc oxide may be sequentially deposited on the substrate S through the gallium zinc oxide deposition step S130, and thus, the gallium zinc oxide may be formed on the substrate S. The gallium zinc oxide deposition step S130 may sequentially perform the gallium oxide sub-cycle GSC and the zinc oxide sub-cycle ZSC a plurality of times. In the gallium zinc oxide deposition step S130, each of the source gas including gallium and the source gas including zinc may be injected toward the substrate S through the first gas flow path 4a, and the reactant gas including oxygen may be injected toward the substrate S through the second gas flow path 4b.

Referring to FIGS. 1 to 6, the deposition cycle step S100 may include the zinc indium oxide deposition step S110, the gallium indium oxide deposition step S120, and the gallium zinc oxide deposition step S130. The deposition cycle step S100 may be implemented to be suitable for depositing the IGZO channel layer 230 consisting of a composition ratio where zinc, indium, and gallium approximately match therebetween. Also, the repetition step S200 may sequentially and repeatedly perform the zinc indium oxide deposition step S110, the gallium indium oxide deposition step S120, and the gallium zinc oxide deposition step S130. Accordingly, the atomic layer deposition method according to the present inventive concept may form the IGZO channel layer 230 by a predetermined thickness on the substrate S.

The deposition cycle step S100 may include the zinc indium oxide deposition step S110 and the gallium indium oxide deposition step S120. In this case, the deposition cycle step S100 does not include the gallium zinc oxide deposition step S130. The deposition cycle step S100 may be implemented to be suitable for depositing the IGZO channel layer 230 consisting of a composition ratio where indium is greater in ratio than each of zinc and gallium. Also, the repetition step S200 may sequentially and repeatedly perform the zinc indium oxide deposition step S110 and the gallium indium oxide deposition step S120.

The deposition cycle step S100 may include the gallium indium oxide deposition step S120 and the gallium zinc oxide deposition step S130. In this case, the deposition cycle step S100 does not include the zinc indium oxide deposition step S110. The deposition cycle step S100 may be implemented to be suitable for depositing the IGZO channel layer 230 consisting of a composition ratio where gallium is greater in ratio than each of indium and zinc. Also, the repetition step S200 may sequentially and repeatedly perform the gallium indium oxide deposition step S120 and the gallium zinc oxide deposition step S130.

The deposition cycle step S100 may include the gallium zinc oxide deposition step S130 and the zinc indium oxide deposition step S110. In this case, the deposition cycle step S100 does not include the gallium indium oxide deposition step S120. The deposition cycle step S100 may be implemented to be suitable for depositing the IGZO channel layer 230 consisting of a composition ratio where zinc is greater in ratio than each of indium and gallium. Also, the repetition step S200 may sequentially and repeatedly perform the gallium zinc oxide deposition step S130 and the zinc indium oxide deposition step S110.

Referring to FIGS. 1 to 7, the deposition cycle step S100 may include a gallium oxide deposition step S140 in addition to including the zinc indium oxide deposition step S110. In this case, the deposition cycle step S100 may not include the gallium indium oxide deposition step S120 and the gallium zinc oxide deposition step S130.

The gallium oxide deposition step S140 may perform the gallium oxide sub-cycle GSC. The gallium oxide may be deposited on the substrate S through the gallium oxide deposition step S140. The gallium oxide deposition step S140 may perform the gallium oxide sub-cycle GSC a plurality of times. The deposition cycle step S100 may be implemented to be suitable for depositing the IGZO channel layer 230 consisting of a composition ratio where zinc, indium, and gallium approximately match therebetween. Also, the repetition step S200 may sequentially and repeatedly perform the zinc indium oxide deposition step S110 and the gallium oxide deposition step S140.

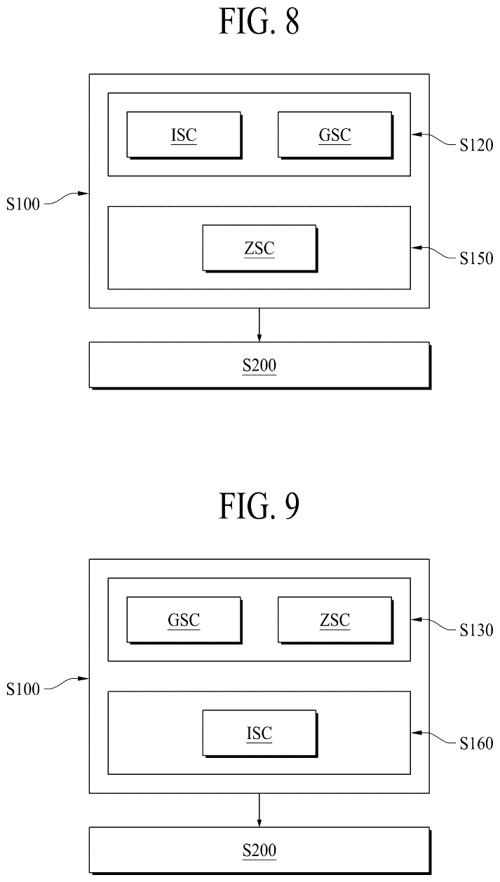

Referring to FIGS. 1 to 8, the deposition cycle step S100 may include a zinc oxide deposition step S150 in addition to including the gallium indium oxide deposition step S120. In this case, the deposition cycle step S100 may not include the zinc indium oxide deposition step S110 and the gallium zinc oxide deposition step S130.

The zinc oxide deposition step S150 may perform the zinc oxide sub-cycle ZSC. The zinc oxide may be deposited on the substrate S through the zinc oxide deposition step S150. The zinc oxide deposition step S150 may perform the zinc oxide sub-cycle ZSC a plurality of times. The deposition cycle step S100 may be implemented to be suitable for depositing the IGZO channel layer 230 consisting of a composition ratio where zinc, indium, and gallium approximately match therebetween. Also, the repetition step S200 may sequentially and repeatedly perform the gallium indium oxide deposition step S120 and the zinc oxide deposition step S150.

Furthermore, the deposition cycle step S100 may be implemented to include the gallium indium oxide deposition step S120, and thus, the atomic layer deposition method according to the present inventive concept may improve a step coverage of the IGZO channel layer 230. The gallium indium oxide deposition step S120 may be performed by depositing indium oxide after gallium oxide is deposited. The gallium indium oxide deposition step S120 may be performed by depositing gallium oxide after indium oxide is deposited.

Referring to FIGS. 1 to 9, the deposition cycle step S100 may include an indium oxide deposition step S160 in addition to including the gallium zinc oxide deposition step S130. In this case, the deposition cycle step S100 may not include the zinc indium oxide deposition step S110 and the gallium indium oxide deposition step S120.

The indium oxide deposition step S160 may perform the indium oxide sub-cycle ISC. The indium oxide may be deposited on the substrate S through the indium oxide deposition step S160. The indium oxide deposition step S160 may perform the indium oxide sub-cycle ISC a plurality of times. The deposition cycle step S100 may be implemented to be suitable for depositing the IGZO channel layer 230 consisting of a composition ratio where zinc, indium, and gallium approximately match therebetween. Also, the repetition step S200 may sequentially and repeatedly perform the gallium zinc oxide deposition step S130 and the indium oxide deposition step S160.

The present inventive concept described above are not limited to the above-described embodiments and the accompanying drawings and those skilled in the art will clearly appreciate that various modifications, deformations, and substitutions are possible without departing from the scope and spirit of the inventive concept.

1. An atomic layer deposition (ALD) method for forming an IGZO channel layer of a transistor device, the atomic layer deposition method comprising:
a deposition cycle step of performing a deposition cycle for depositing an IGZO channel layer on a substrate; and
a repetition step of repeatedly performing the deposition cycle step until the IGZO channel layer having a predetermined thickness is formed,
wherein the deposition cycle step performs an indium oxide sub-cycle for depositing indium oxide (InO), a gallium oxide sub-cycle for depositing gallium oxide (GaO), and a zinc oxide sub-cycle for depositing zinc oxide (ZnO) to deposit the IGZO channel layer.

2. The atomic layer deposition method of claim 1, wherein
the indium oxide sub-cycle sequentially performs, at least once, injection of a source gas including indium (In) and injection of a reactant gas including oxygen (O) to deposit indium oxide through atomic layer deposition,
the gallium oxide sub-cycle sequentially performs, at least once, injection of a source gas including gallium (Ga) and injection of a reactant gas including oxygen (O) to deposit gallium oxide through atomic layer deposition, and
the zinc oxide sub-cycle sequentially performs, at least once, injection of a source gas including zinc (Zn) and injection of a reactant gas including oxygen (O) to deposit zinc oxide through atomic layer deposition.

3. The atomic layer deposition method of claim 1, wherein the deposition cycle step comprises:
a zinc indium oxide deposition step of sequentially performing the zinc oxide sub-cycle and the indium oxide sub-cycle at least once;
a gallium indium oxide deposition step of sequentially performing the gallium oxide sub-cycle and the indium oxide sub-cycle at least once; and
a gallium zinc oxide deposition step of sequentially performing the gallium oxide sub-cycle and the zinc oxide sub-cycle at least once.

4. The atomic layer deposition method of claim 3, wherein the repetition step sequentially and repeatedly performs the zinc indium oxide deposition step, the gallium indium oxide deposition step, and the gallium zinc oxide deposition step.

5. The atomic layer deposition method of claim 1, wherein the deposition cycle step comprises:
a zinc indium oxide deposition step of sequentially performing the zinc oxide sub-cycle and the indium oxide sub-cycle at least once; and
a gallium indium oxide deposition step of sequentially performing the gallium oxide sub-cycle and the indium oxide sub-cycle at least once.

6. The atomic layer deposition method of claim 1, wherein the deposition cycle step comprises:
a gallium indium oxide deposition step of sequentially performing the gallium oxide sub-cycle and the indium oxide sub-cycle at least once; and
a gallium zinc oxide deposition step of sequentially performing the gallium oxide sub-cycle and the zinc oxide sub-cycle at least once.

7. The atomic layer deposition method of claim 1, wherein the deposition cycle step comprises:
a gallium zinc oxide deposition step of sequentially performing the gallium oxide sub-cycle and the zinc oxide sub-cycle at least once; and
a zinc indium oxide deposition step of sequentially performing the zinc oxide sub-cycle and the indium oxide sub-cycle at least once.

8. The atomic layer deposition method of claim 1, wherein the deposition cycle step comprises:
a zinc indium oxide deposition step of sequentially performing the zinc oxide sub-cycle and the indium oxide sub-cycle at least once; and
a gallium oxide deposition step of performing the gallium oxide sub-cycle at least once.

9. The atomic layer deposition method of claim 1, wherein the deposition cycle step comprises:
a gallium zinc oxide deposition step of sequentially performing the gallium oxide sub-cycle and the zinc oxide sub-cycle at least once; and
an indium oxide deposition step of performing the indium oxide sub-cycle at least once.

10. An atomic layer deposition (ALD) method for forming an IGZO channel layer of a transistor device, the atomic layer deposition method comprising:
a deposition cycle step of performing a deposition cycle for depositing an IGZO channel layer on a substrate; and
a repetition step of repeatedly performing the deposition cycle step until the IGZO channel layer having a predetermined thickness is formed,
wherein the deposition cycle step comprises:
a gallium indium oxide deposition step of sequentially performing, at least once, a gallium oxide sub-cycle for depositing gallium oxide (GaO) and an indium oxide sub-cycle for depositing indium oxide (InO); and
a zinc oxide deposition step of performing, at least once, a zinc oxide sub-cycle for depositing zinc oxide (ZnO).

11. An atomic layer deposition (ALD) method for forming an IGZO channel layer of a transistor device, the atomic layer deposition method comprising:
a deposition cycle step of performing a deposition cycle for depositing an IGZO channel layer on a substrate; and
a repetition step of repeatedly performing the deposition cycle step until the IGZO channel layer having a predetermined thickness is formed,
wherein the deposition cycle step comprises:
a gallium indium oxide deposition step of sequentially performing, at least once, an indium oxide sub-cycle for depositing indium oxide (InO) and a gallium oxide sub-cycle for depositing gallium oxide (GaO); and
a zinc oxide deposition step of performing, at least once, a zinc oxide sub-cycle for depositing zinc oxide (ZnO).
